(19) United States
(12) Patent Application Publication
(10) Pub. No.: US 2026/0094643 A1
(43) Pub. Date: Apr. 2, 2026

(54) READ SIGNAL OUTPUT TERMINAL DRIVER

(71) Applicant: Arm Limited, Cambridge (GB)

(72) Inventors: Rajiv Kumar Sisodia, Bangalore (IN); Disha Singh, Bangalore (IN); Andy Wangkun Chen, Austin, TX (US); Akash Bangalore Srinivasa, Bangalore (IN); Arjunesh Namboothiri Madhavan, Bangalore (IN)

(21) Appl. No.: 18/904,495

(22) Filed: Oct. 2, 2024

(51) Int. Cl. G11C 11/419; G11C 11/412; H03K 19/20

(52) U.S. Cl. CPC G11C 11/419; H03K 19/20; G11C 11/412

(57) ABSTRACT

Briefly, example apparatuses, articles of manufacture, and/or techniques are disclosed that may be implemented, in whole or in part, to implement, facilitate and/or support integrated circuits comprising memory read output circuitry including a read signal input terminal, a latch, and a combinatorial gate coupled to the read signal input terminal and the latch.

### FIELD

The present disclosure relates generally to integrated circuitry, and more particularly, read signal output terminal circuitry.

### BACKGROUND

Integrated circuits (ICs) that include memory circuitry may use precharge techniques when reading stored data. In some such circuits, a bitline used to read an individual bit of data may be precharged to a logic voltage level. During a read cycle, the bitline is modulated according to a stored state of a corresponding memory cell. In some examples, the bitline may remain at the precharged voltage level to indicate a first data value (e.g., a binary 0) and may drop to a low/ground voltage level to indicate a second data value (e.g., a binary 1).

### BRIEF DESCRIPTION OF THE FIGURES

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1 illustrates an example apparatus including a memory read output circuit in accordance with an implementation;

FIG. 2 illustrates an example of signaling during operation of a memory read output circuit in accordance with an implementation;

FIG. 3 illustrates another example apparatus including a memory read output circuit in accordance with an implementation;

FIG. 4 illustrates results of a comparative simulation of a memory read output circuit in accordance with an implementation;

FIG. 5 illustrates an example memory system including memory read output circuitry in accordance with an implementation;

FIG. 6 illustrates an example method of circuit operation in accordance with an implementation; and

FIG. 7 illustrates an example non-transitory computer-readable medium comprising computer-readable code for a design of an apparatus in accordance with an implementation.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others, one or more aspects, properties, etc. may be omitted, such as for ease of discussion, or the like. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. Therefore, the following detailed description is not to be taken to limit claimed subject matter and/or equivalents.

### DETAILED DESCRIPTION

References throughout this specification to one implementation, an implementation, one embodiment, an embodiment, and/or the like means that a particular feature, structure, characteristic, and/or the like described in relation to a particular example, implementation and/or embodiment is included in at least one example, implementation and/or embodiment of claimed subject matter. Thus, appearances of such phrases, for example, in various places throughout this specification are not necessarily intended to refer to the same implementation and/or embodiment and/or to any one particular implementation and/or embodiment.

Furthermore, it is to be understood that particular features, structures, characteristics, and/or the like described are capable of being combined in various ways in one or more implementations and/or embodiments and, therefore, are within intended claim scope. Unless explicitly indicated to the contrary, reference to “another example” and/or “a further example” does not indicate that the described example is an exclusive alternative to a preceding example. In general, such examples may be alternatives to and/or additions to previous examples.

In the following and without loss of generality, a binary 0 will be described as corresponding to a high voltage on a bitline, and a binary 1 will be described as corresponding to a low voltage on the bitline. Of course, this is a convention for ease of explanation and implementations may utilize other logic to voltage level mappings without departing from the scope of the described technology.

Some integrated circuits (ICs) having memory circuitry may include read circuitry to output a stored state during a memory read cycle. In some cases, the read circuitry may include a latch coupled to a bitline, which carries the stored state being read. During a memory read cycle, the latch may be connected to the bitline (e.g., via a transmission gate) in response to a sense signal, and, when connected, capture and store the state of the bitline. In these examples, the latch state may drive an output terminal of the read circuitry during the read cycle. If the sense signal arrives before the bitline has settled to the read state, the latch may store an incorrect state. For example, when reading a stored 1, if the sense signal arrives before the bitline has settled to low voltage, the latch may incorrectly store a 0 (e.g., a high voltage). Accordingly, the sense signal may be delayed compared to a read signal beginning the read cycle, which may impact read access time.

Aspects of the disclosed technology may provide memory read output circuitry that addresses challenges such as these examples. For example, some implementations may directly drive a read output terminal by a bitline in response to a discharged bitline read case and by driving the read output terminal by a latch in a charged bitline read case.

In some implementations, memory read output circuitry may include a precharged read signal input terminal which enters a discharge state during the read cycle to indicate a first signal value (e.g., 1). Example circuitry may further include a latch and a transmission gate to capture the input terminal state responsive to a sense signal. Example circuitry may further include a combinatorial gate connected to a read signal output terminal. The example combinatorial gate may include a first gate input terminal coupled to the read signal input terminal, and a second gate input terminal coupled to the latch. In some examples, the first gate input terminal may drive the read signal output terminal during the read cycle responsive to the read signal input terminal in the discharge state.

Further aspects of the disclosed technology may provide a method of operating memory read output circuitry. In some implementations, a method may include sensing a state of a read signal input terminal and retaining the state in a latch. Example methods may further include driving a read signal output terminal via the read signal input terminal responsive to a discharge state at the read signal input terminal.

Still further aspects of the disclosed technology may provide computer-readable medium storing computer-readable code for the fabrication of an apparatus as described above and/or an apparatus to function as described above.

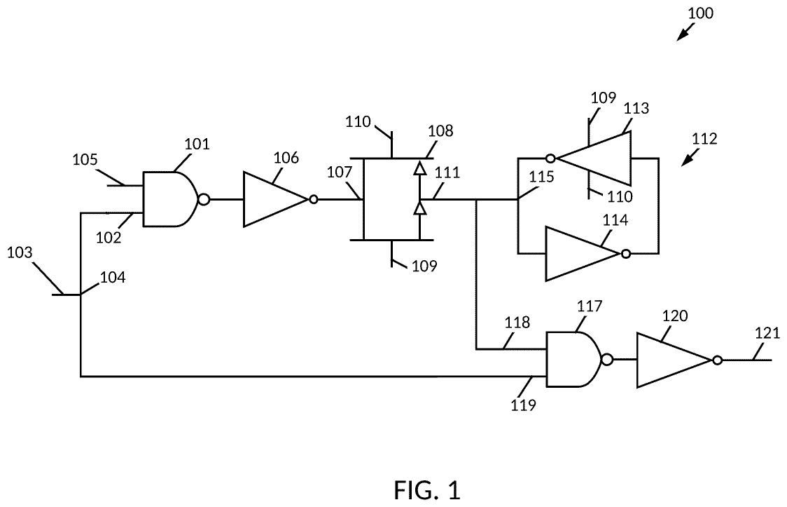

FIG. 1 illustrates an example implementation of memory read output circuit 100. For example, circuit 100 may comprise a read port of a memory circuit, such as a static random access memory (SRAM), dynamic RAM (DRAM), resistive RAM, phase-change RAM, or other memory circuit. As a particular example, circuit 100 may comprise read circuitry for an 8-transistor (8T) SRAM memory cell.

In some implementations, circuit 100 may include a read signal input terminal 104. Read signal input terminal 104 may receive data signals corresponding to stored data. In some implementations, read signal input terminal 104 may be in a precharge state prior to a read cycle. For example, read signal input terminal 104 may be coupled to a bitline 103 that is precharged to a high voltage (e.g., Vdd) between read cycles. In some implementations, during a read cycle, read signal input terminal 104 may be transition to a discharge state or remain in the precharge state. For instance, the discharge state may indicate a first signal value (e.g., a 1) and the precharge state may indicate a second signal value (e.g., a 0).

In the illustrated example, read signal input terminal 104 may be coupled to a first input terminal 102 of a NAND gate 101. For instance, in some implementations, circuit 100 may comprise be utilized for multiple operations, such as a write data input terminal and a read data output terminal. For example, in such an implementation, NAND gate 101 may have a second terminal 105 coupled to a second signal line, such as a write data input line. As another example, circuit 100 may be one of a bank of such circuits 100 and second terminal 105 may be operated as a select signal to select a particular instance of circuit 100.

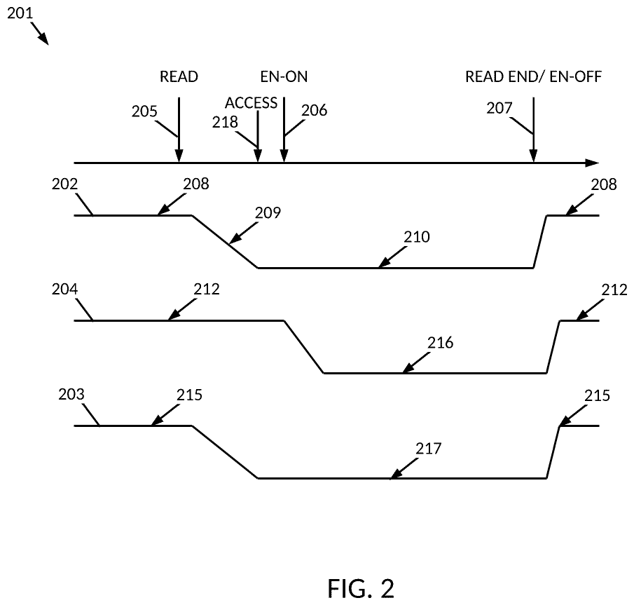

In some implementations, circuit 100 may further comprise an inverter 106 coupled to an output terminal of NAND gate 101. An output of inverter 106 may be connected to an input terminal 107 of a transmission gate 108. For example, in the illustrated implementation, inverter 106 may restore the original polarity of a signal received via bitline 103 (e.g., to restore the polarity after inversion via NAND gate 101). In further implementations, inverter 106 may be at other circuit locations, such as between an output 111 of transmission gate 108 and a latch 112 or prior to an input terminal 118 of an output combinatorial gate 117. In some implementations, inverter 106 may be omitted. For example, in a circuit 100 without a NAND gate 101, transmission gate input 107 may comprise read signal input terminal 104. As another example, circuit 100 may operate on signals that have opposite polarity compared to bitline 103 (see FIG. 2, for example).

In some implementations, circuit 100 may further comprise a transmission gate 108. Transmission gate 108 may include a transmission gate input terminal 107 coupled to read signal input terminal 104. For example, in the illustrated implementation, transmission gate input terminal 107 may be coupled to read signal input terminal 104 via NAND gate 101 and inverter 106. In further implementations, transmission gate input terminal 107 may be coupled directly to transmission gate input terminal 104 or in any other suitable manner. Transmission gate 108 may further comprise a transmission gate output terminal 111 coupled to a latch input/output terminal 115. For example, in a complementary metal oxide semiconductor (cMOS) implementation, transmission gate 108 may comprise a pair of complementary metal oxide field effect transistors (MOSFET), including an n-type transistor (nMOS) and a p-type transistor (pMOS) coupled in parallel with the drain and source terminals of the pair coupled together. Further examples may be implemented using any suitable logic family technology, such as, for example, Magento-Electric Spin-Orbit (MESO) logic, tunnel FETs, spintronics, etc . . .

In some implementations, transmission gate 108 may switchably couple read signal input terminal 104 to latch input/output terminal 115 responsive to a sense signal. For example, transmission gate 108 may comprise a sense signal input terminal to receive the sense signal. In some implementations, such as a cMOS implementation, the sense signal input terminal may comprise a first gate terminal 109 to receive a first sense signal and a second gate terminal 110 to receive a second sense signal. For example, the first sense signal may comprise an enable signal (EN) and the second sense signal may comprise an inversion of the enable signal (EN_n) (e.g., when EN is in a high voltage state, EN_n is in a low voltage state, and vice versa). In some implementations, transmission gate 108 may have an on state responsive to a first signal value (e.g., an EN-ON signal) and an off state responsive to a second signal value (e.g., an EN-OFF signal). For instance, EN-ON may comprise a high EN and low EN_n voltage and EN-OFF may comprise a low EN voltage and a high EN_n voltage). In some implementations, transmission gate 108 may transmit signals between its input terminal 107 and output terminal 111 responsive to EN-ON and may block signals responsive to EN-OFF. For example, in a cMOS implementation, EN-ON may comprise a high voltage at nMOS terminal 109 and a low voltage at pMOS terminal 110, switching both transistors to their on state. In this example, EN-OFF may comprise a low voltage an nMOS terminal 109 and a high voltage at pMOS terminal 110, switching both transistors to their off state. Accordingly, transmission gate 108 may logically connect and disconnect latch 112 to read signal input terminal 104 and bitline 103 responsive to EN-ON and EN-OFF, respectively.

In some implementations, circuit 100 may further comprise a latch 112 to retain a state at a latch input/output (IO) terminal 115. For example, latch 112 may comprise a tri-state latch to retain a state at IO terminal 115 responsive to a sense signal. In some implementations, the latch sense signal may be a common sense signal with the transmission gate sense signal. For instance, latch 112 may comprise cascaded inverters 114, 113, including a tri-state inverter 113. In an example cMOS implementation, tri-state inverter 113 may comprise a pair of sense signal terminals coupled to EN signal line 109 and EN_n signal line 110, respectively. In further implementations, latch 112 may comprise any other suitable latch design, including a flip-flop and/or dual-ported implementation.

In some implementations, tri-state inverter 113 may be in a low impedance state (e.g., on state) responsive to EN-ON and in a high impedance state (e.g., off state) responsive to EN-OFF. In its on state, latch 112 may be enabled to retain a voltage at IO terminal 115 corresponding to a charged or discharged state of bitline 103. For example, in the illustrated implementation, with two inversions at NAND 101 and inverter 106, the IO terminal voltage may have the same polarity as the bitline voltage 113. In other implementations, having an odd number of inversions, for example, the IO terminal voltage may have the opposite polarity as bitline 103.

In some implementations, circuit 100 may further comprise a combinatorial gate 117. Combinatorial gate may 117 may comprise a gate output terminal coupled to read signal output terminal 122 as well as a first gate input terminal 119 coupled to read signal input terminal 104, and a second gate input terminal 118 coupled to latch IO terminal 115. In some implementations, combinatorial gate 117 may comprise a NAND gate 117. Further implementations may employ other combinatorial gate types. For example, FIG. 2 illustrates an example implementation comprising a NOR gate as a combinatorial gate. In some implementations, the output terminal of NAND gate 117 may coupled to an input terminal of an inverter 120 and read signal output terminal 121 may comprise an output of inverter 120. In some implementations, read signal output terminal 121 may output voltage signals at the same logic levels as bitline 103 (e.g., if a high voltage on bitline 103 corresponds to 0, then a high voltage on read signal output terminal 121 also corresponds to 0, and vice versa). In further implementations, read signal output terminal 121 may output voltage signals at the opposite polarity as bitline 103 (e.g., if a high voltage on bitline 103 corresponds to 0, then a high voltage on read signal output terminal 121 corresponds to 1, and vice versa). For instance, in some such implementations, a second inverter 120 may be added in serial to the first inverter 120. As another example, inverter 120 may be omitted and read signal output terminal 121 may comprise the output terminal of NAND 117.

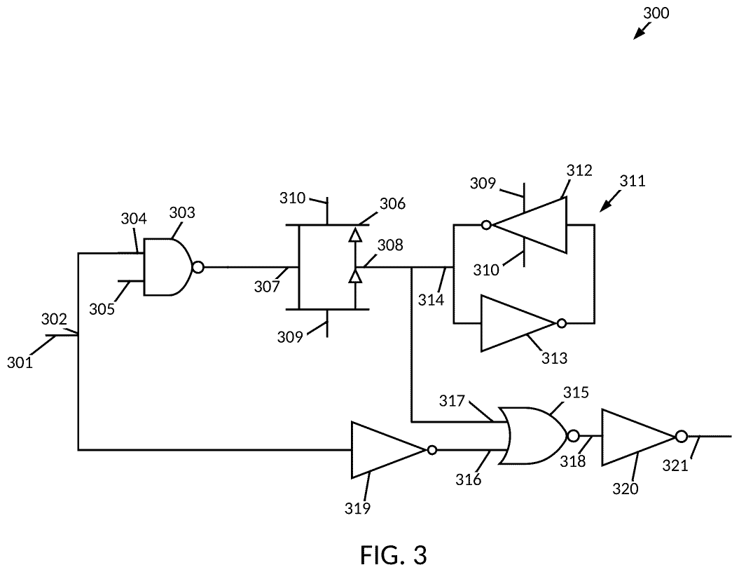

In some implementations, input signals to combinatorial gate 117 may cooperate to drive an output voltage at read signal output terminal 122. For example, read signal input terminal 104 may drive read signal output terminal 122 during a read cycle responsive to read signal input terminal 104 in the discharge state. For instance, in the illustrated example, read signal input terminal 104 may be coupled to bitline 103 to be in a high voltage state when bitline 103 is a high voltage precharge state and to be in a low voltage state when bitline 103 is in a low voltage discharge state. Similarly, in the illustrated example, second gate input 118 has a voltage driven by latch IO 115 to be in a high voltage state when latch IO 115 is in a high voltage state, and vice versa. An example of the operation of circuit 100 is described below with respect to FIG. 3.

Attention is now drawn to FIG. 2, which illustrates an example timing diagram 201 of a discharge memory read. For example, diagram 201 may represent an implementation of circuit 100 during a read cycle when a memory read results in a discharged bitline. In the illustrated example, signal 202 illustrates an example bitline voltage state, signal 203 illustrates an example latch voltage state, and signal 204 illustrates an example memory read output voltage state. For instance, signal 202 may illustrate a voltage on bitline 103 and/or 202, signal 203 may illustrate a voltage on latch output terminal 115 and/or 214.

In the illustrated example, a read cycle may comprise a time period between an initial read command 205 and a read cycle end 207 (e.g., the end of a predetermined read time period, an end command, such as EN-OFF, and/or the like). Here, prior to read command 205, the bitline is precharged and signal 202 comprises a high voltage state 208. After read command 205, the bitline is discharged and signal 202 transitions 209 to a low voltage state 210. In the illustrated example, sense signal 206 arrives a predetermined time after read command 205. Prior to sense signal 206, the latch is switchably decoupled from the bitline and signal 203 remains in a high voltage state 213. For example, as discussed above, sense signal 206 may be timed to arrive after transition 209. After sense signal 206, the latch follows signal 202 and transitions to a low voltage state 216. In some implementations, the bitline may drive the output terminal prior to the sense signal. In the illustrated example, signal 204 follows signal 202 and enters the low voltage state 217 after read command 205 and returns to the high voltage state 214 after read cycle end 207. Accordingly, prior to sense signal 206, bitline signal 202 drives output signal 204. After arrival of sense signal 206, latch signal 203 may drive output signal 204 and/or may cooperate with bitline signal 202 to drive output signal 204. Here, the earliest potential access time 218 may precede the latch output signal 203 and may proceed sense signal 206. In this example, memory read output signal 204 initially enters the correct low voltage state 217 while latch output signal 203 remains in the high voltage state 213. As illustrate, arrival of sense signal 206 with respect to transition 209 does not influence memory read output signal 204. Accordingly, sense signal 206 may be timed earlier, such as, for example, simultaneously with read command 205.

Attention is now drawn to FIG. 3, which illustrates an example circuit 300 comprising a NOR combinatorial gate. For example, circuit 300 may comprise read circuitry such as described with respect to FIG. 1. For instance, circuit 300 may comprise a read port of a memory circuit, such as a static random access memory (SRAM), dynamic RAM (DRAM), resistive RAM, phase-change RAM, or other memory circuit. As a particular example, circuit 300 may comprise read circuitry of an 8-transistor (8T) SRAM memory cell.

In some implementations, circuit 300 may comprise a read signal input terminal 302 coupled to a latch 311 and a combinatorial gate 315. For example, read signal input terminal 302 may be implemented as described with respect to read signal input terminal 104. In further implementations, read signal input terminal 302 may be coupled to a bitline 301. For instance, bitline 301 may be a precharged memory read bitline as described with respect to bitline 103. For example, bitline 301 may be precharged to a high voltage prior to a read cycle. Depending on a value stored in a memory cell being read, bitline 301 may remain at the precharged voltage or may drop to a discharged voltage.

In some implementations, circuit 300 may further comprise input terminal circuitry such as a NAND gate 303. For example, read signal input terminal 302 may be coupled to a first input terminal 304 of NAND gate 303. In this implementation, NAND gate 305 may comprise a second input terminal 305. For instance, input terminals 304, 305 and NAND gate 305 may be implemented as described with respect to input terminals 101, 102, and NAND gate 101, respectively.

In some implementations, NAND gate 303 may have an output terminal coupled to a transmission gate input terminal 307 of a transmission gate 306. Transmission gate 306 may further comprise an output terminal 308 coupled to a latch input/output (IO) terminal 314. In some implementations, transmission gate 306 may comprise sense signal input terminals 309, 310. For example, transmission gate 306 may be implemented as described with respect to transmission gate 108. Compared to circuit 100, circuit 300 may lack an inverter between NAND gate 303 and transmission gate 306 (e.g., inverter 106). Accordingly, in the illustrated example, the latch input terminal 307 may be at an opposite polarity as bitline 301. For example, when bitline 301 is in a high voltage precharge state, transmission gate input terminal 307 may be in a low voltage precharge state. Similarly, when bitline 301 is in a low voltage discharge state, transmission gate input terminal 307 may be in a high voltage discharge state.

In some implementations, transmission gate output terminal 308 may be coupled to a latch IO terminal 314 of a latch 311. For example, latch 311 may be implemented as described with respect to latch 112. For instance, latch 311 may comprise a cascaded pair of inverters 312, 313. In some implementations, at least one inverter 312 may comprise a tri-state inverter comprising a latch sense control signal input. For example, inverter 312 may be coupled to sense signal lines 309 and 310 to receive a common sense signal with transmission gate 306. As indicated above, during operation, latch 311 may retain a voltage signal having an opposite polarity as bitline 301. For example, latch 311 may retain a low voltage precharge signal responsive to a sense signal and bitline 301 in a high voltage precharge state. Similarly, latch 311 may retain a high voltage discharge signal responsive to the sense signal and bitline 301 in a low voltage discharge state.

In some implementations, circuit 300 may further comprise a combinatorial gate 315. In the illustrated implementation, combinatorial gate 315 may comprise a NOR gate 315. NOR gate 315 may comprise a first input terminal 316 coupled to read signal input terminal 302. In some implementations, input terminal 316 may be coupled to read signal input terminal 302 via an inverter 319. Accordingly, read signal input terminal 302 and input terminal 302 may be at opposite polarities. NOR gate 315 may further comprise an output terminal 318 coupled to a read signal output terminal 321. As indicated above, circuit 300 may output logic voltage levels of opposite polarity as bitline 301. For example, in some implementations, circuit 300 may comprise an inverter 320 coupled to NOR gate output terminal 318 and the output of inverter 320 may comprise read signal output terminal 321.

In implementations as illustrated, inputs 317 and 316 may be at a low voltage prior to a read cycle. In some examples, responsive to a precharge memory read, inputs 317 and 316 may remain in the precharge low voltage state. In this case, NOR gate 315 may output a high voltage (e.g., NOR(0,0)=1) and read signal input terminal 321 may output a low voltage.

Similarly, responsive to a discharge memory read, inputs 316 and 317 may transition to a high voltage discharge state. Here, NOR gate 315 may output a low voltage (e.g., NOR(1,1)=0) and read signal output terminal 321 may output a high voltage. In some implementations, input 317 may transition to a high voltage discharge state after circuit 300 receives a sense signal via inputs 309, 310. Accordingly, input 316 may therefore transition to a high voltage discharge state prior to input 317. However, in this case, NOR gate 315 may still output a low voltage (e.g., NOR(1,0)=0). Accordingly, responsive to a discharge memory read, read signal input terminal 302 may drive read signal output terminal 321 for at least an initial portion of a read cycle. For example, a discharge memory read cycle may proceed as described with respect to FIG. 2 except that signals 204 and 203 would be inverted.

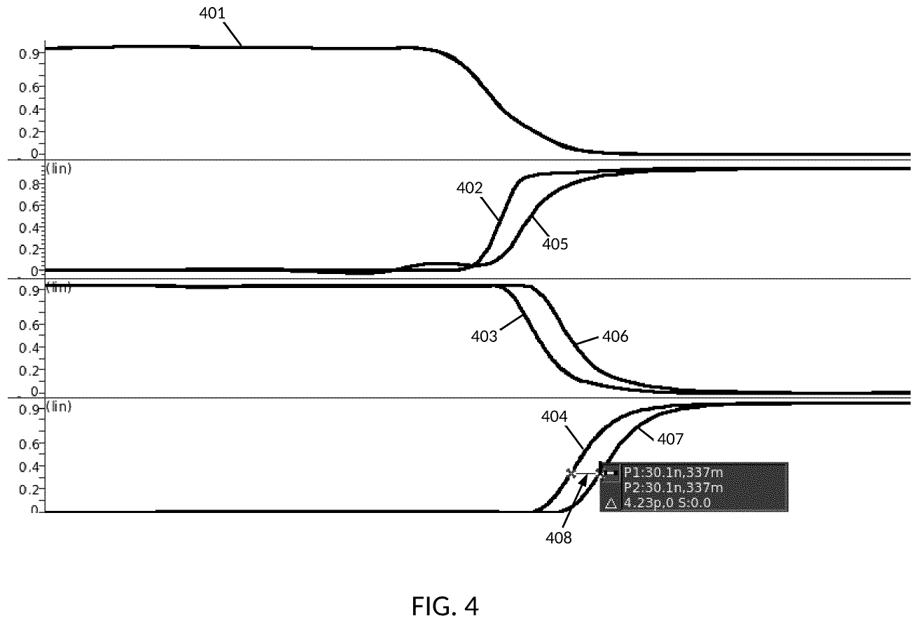

Attention is now drawn to FIG. 4, which illustrates an example of simulation results comparing a simulated circuit in accordance with circuit 301 to a hypothetical circuit lacking inverter 319 and input 317 (e.g., the hypothetical comparison comprised an inverter coupled to the latch IO terminal in place of combinatorial gate 315). In this example, signal 401 represents a bitline voltage of both circuits. Signal 402 illustrates simulated voltages at latch IO terminal 314, signal 403 represents a simulated output of NOR gate 315, and signal 404 represents simulated voltages at memory read output terminal 321. In this example, signals 405, 406, and 407 illustrate example simulated outputs of the comparative circuit at corresponding locations. The simulated implementation was found to demonstrate a 4% faster access time 408 compared to the simulated comparison circuit.

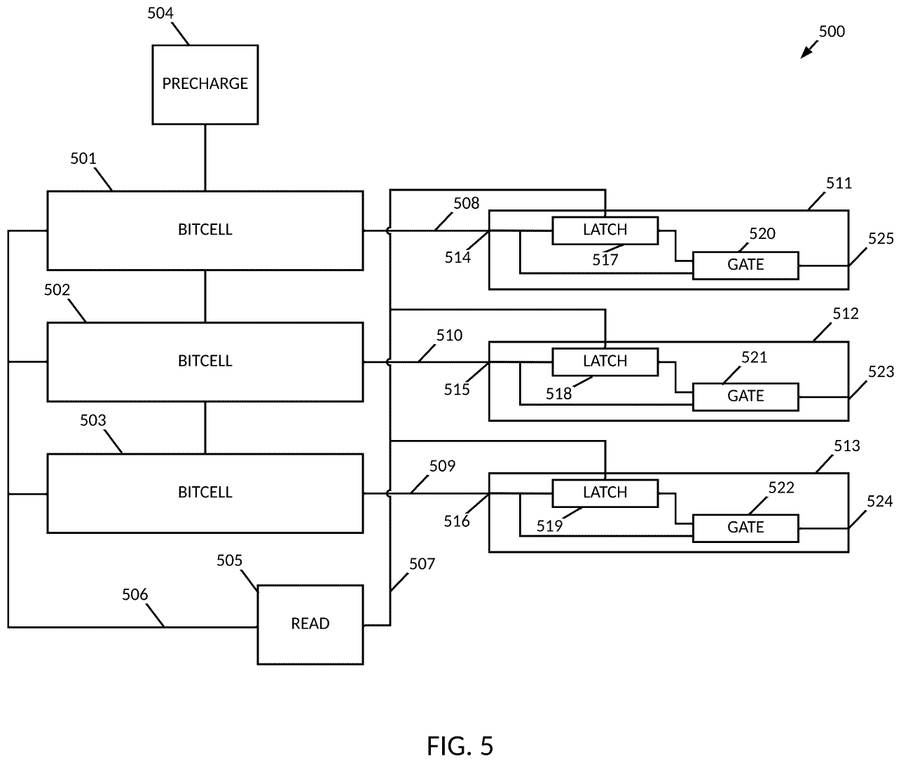

Attention is now drawn to FIG. 5, which illustrates an example memory system 500 in accordance with an implementation. In some implementations, memory system 500 may comprise a plurality of bitcells 501, 502, 503 and corresponding memory read output circuits 511, 512, 513. For example, bitcells 501, 502, 503 may comprise memory cells such as SRAM, DRAM, resistive RAM, phase-change RAM, or other memory circuit implementing precharged memory reads. Bitcells 501-503 may comprise 8-transistor (8T) SRAM memory cells.

In some implementations, bitcells 501, 502, 503 may comprise a plurality of bitlines 508, 509, 510, respectively. Memory system 500 may further comprise precharge circuitry 504 to precharge bitlines 508-510 to a high voltage precharge state between read cycles. Memory system 500 may further comprise read control circuitry 505. In some implementations, read control circuitry 505 may transmit read control signals via read control signal line 506. For example, read control circuitry 505 may generate read control signals for individual and/or groups of bitlines responsive to a read command, such as a read command identifying which bitline(s) to read.

In some implementations, a memory read cycle may comprise modulating a bitline 508-510 responsive to a storage state of a corresponding bitcell 501-503. For example, in response to bitcell 501-503 having a first stored state indicative of a first data value, a corresponding bitline 508-510 may remain at a high voltage (e.g., a precharge memory read). Similarly, in response to bitcell 501-503 having a second stored state indicative of a second data value, corresponding bitline 508-510 may be driven to a low voltage (e.g., a discharge memory read).

In some implementations, memory read circuitry 500 may further comprise memory read output circuits 511, 512, 513 to output signals indicative of the stored state of corresponding bitcells 501, 502, 503. For example, memory read output circuits 511, 512, 513 may be implemented as described with respect to memory read output circuits 100, 300, or other described implementation. In some implementations, bitlines 508, 509, 510 may be coupled to read signal input terminals 514, 515, 516. For example, read signal input terminals 514, 515, 516 may be as described with respect to read signal input terminal 104 and/or 302.

In some implementations, memory read output circuits 511, 512, 513 may comprise corresponding latches 517, 518, 519, and combinatorial gates 520, 521, 522 coupled to read signal input terminals 514, 515, 516. Additionally, latches 517, 518, 519 may be connected to read control circuitry 505 via sense signal lines 507. Read control circuitry 505 may generate sense signals responsive to read commands as described above. For example, latches 517, 518, 519 may be implemented as described with respect to latch 112 and/or latch 311. In some such examples, memory read output circuits 511, 512, 513 may comprise additional circuitry coupling latches 517-519 to read signal input terminals 517-519, such as, for example, transmission gates, other combinatorial gates, inverters, and/or like circuit elements as described above.

In some implementations, combinatorial gates 520, 521, 522 may comprise inputs coupled to read signal input terminals 514-516 as well as latches 517-519. For example, combinatorial gates 520-522 may comprise NAND gates as described with respect to NAND gate 117. In further implementations, combinatorial gates 520-522 may comprise NOR gates as described with respect to NOR gate 315.

In some implementations, memory read output circuits 511-513 may further comprise read signal output terminals 523-525. For example, read signal output terminals 523-525 may be implemented as described with respect to read signal output terminals 121 and/or 321. As indicated above, responsive to a discharge memory read, bitlines 508-510 may drive read signal output terminals 523-524 prior to a sense signal and/or while latches 517-519 transition their discharge voltage state. Accordingly, read data signals output via terminals 523-525 may reflect the voltage state of bitlines 508-510 regardless of the voltage states of latches 517-519. As indicated above, in some implementations, sense signals may therefore be transmitted by read control circuitry 505 earlier relative to circuits lacking the parallel path from bitline 508-510 to output terminal 523-525 provided by combinatorial gates 520-522.

In further implementations, memory read output circuits 511-513 may comprise circuit elements to adjust a polarity of a memory read signal received via bitlines 508-510. For instance, as described with respect to FIG. 3, circuits 511-513 may comprise inverters (e.g., inverters 319 and NAND gate 303) such that the input signals to combinatorial gates 520-522 have an opposite polarity to bitline 508-510. As another example, circuits 511-513 may comprise circuit elements as described with respect to inverter 120 and/or inverter 320 to place the output in particular logic level voltage polarity (e.g., logic high or logic low).

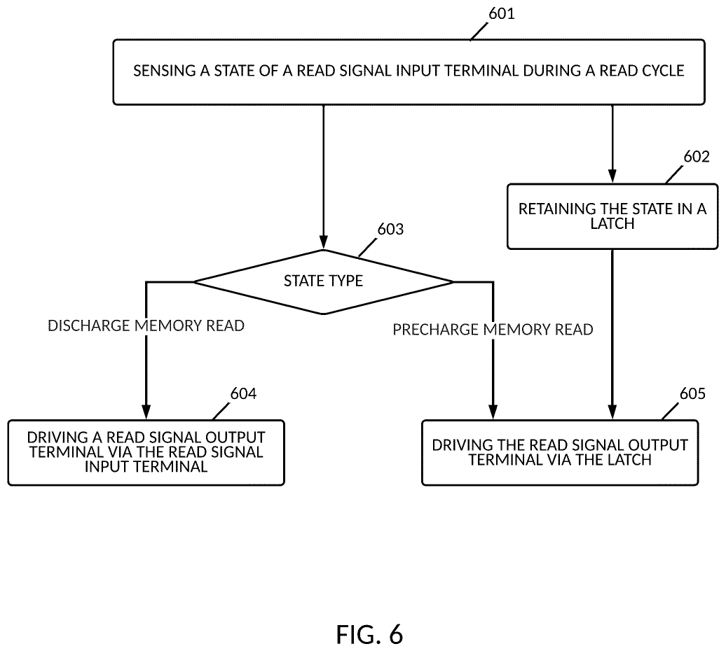

Attention is now drawn to FIG. 6, which is a flow diagram illustrating a method of operating a circuit. For instance, in some implementations, any example circuit described with respect to FIGS. 1, 3, and/or 5 may be operated as illustrated.

In some implementations, the method may include operation 601, which may include sensing a state of a read signal input terminal during a read cycle. For example, in some cases, operation 601 may comprise receiving a voltage signal via a bitline corresponding to the state. In some implementations, the state may be a precharge state corresponding to a high voltage signal from the bitline. For instance, the precharge state may correspond to a high voltage to which the bitline is precharged before the read cycle. In this example, the bitline may remain in the precharge high voltage state to indicate of a first data value stored by a bitcell coupled to the bitline. In this example, the discharge state may correspond to a low voltage signal to which the bitline is driven responsive to a second data value stored by the bitcell. For example, operation 601 may be performed as described with respect to bitline 103 and data signal input terminal 104 and/or bitline 301 and data signal input terminal 302.

In some implementations, the method may further include operation 602, which may include retaining the state sensed in operation 601 in a latch. In some implementations, operation 602 may be performed responsive to a sense signal received during read cycle. For example, operation 602 may comprise enabling a transmission gate and placing a tri-state latch into a low impedance state in response to a sense signal. For instance, operation 602 may be performed as described with respect to transmission gate 108 and latch 112 and/or transmission gate 306 and latch 311.

In some implementations, the method may include performing operations 604 and/or 605 based on a state type 603 sensed in operation 601. For example, the method may include operation 604, which may comprise driving the read signal output terminal via the read signal input terminal. In some implementations, operation 604 may be performed responsive to receiving a discharged voltage signal via the bitline.

For example, operation 604 may be performed as described with respect to driving read signal output terminal 121 via combinatorial gate input 119 and/or driving read signal output terminal 321 via combinatorial gate input 316. Accordingly, as discussed above, in some cases, operation 604 may be performed prior to or in parallel with operation 602.

In some implementations, the method may further comprise operation 605, which may include driving the read signal output terminal via the latch. For example, operation 605 may be performed responsive to receiving a precharged voltage signal via the bitline. In some implementations, operation 605 may be performed as described with respect to driving read signal output terminal 121 via combinatorial gate input 118 and/or driving read signal output terminal 321 via combinatorial gate input 317. For example, the latch output may be at the precharge state prior to the read cycle. Accordingly, when the read cycle commences, the latch output may remain in its previous state and may drive the read signal output terminal immediately.

In further implementations, aspects of operations 604 and 605 may be performed in parallel. For example, as described above, operations 604 and 605 may be performed via a combinatorial gate, such as NAND gate 117 or NOR gate 315. In some implementations, the read signal input terminal and the latch may cooperate to drive the read signal output terminal during portions of a read cycle. For instance, during a discharge read event, the read signal input terminal and the latch may cooperate to drive the read signal output terminal after the latch settles to its discharge state following a sense signal. As another example, during a precharge read event, the read signal input terminal and the latch may cooperate to drive the read signal output terminal immediately following the sense signal.

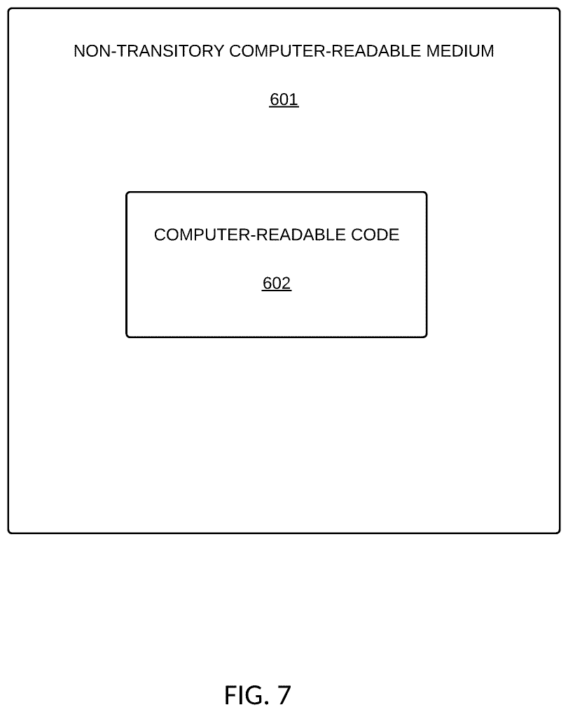

Attention is now drawn to FIG. 7, which illustrates an example of a non-transitory computer-readable medium 701 comprising computer-readable code 702.

Concepts described herein may be embodied in computer-readable code 702 for fabrication of an apparatus that embodies the described concepts. For example, the computer-readable code 702 can be used at one or more stages of a semiconductor design and fabrication process, including an electronic design automation (EDA) stage, to fabricate an integrated circuit comprising the apparatus embodying the concepts.

The above computer-readable code 702 may additionally or alternatively enable the definition, modeling, simulation, verification and/or testing of an apparatus embodying the concepts described herein.

For example, the computer-readable code 702 for fabrication of an apparatus embodying the concepts described herein can be embodied in code 702 defining a hardware description language (HDL) representation of the concepts. For example, the code 702 may define a register-transfer-level (RTL) abstraction of one or more logic circuits for defining an apparatus embodying the concepts. The code 702 may define a HDL representation of the one or more logic circuits embodying the apparatus in Verilog, SystemVerilog, Chisel, or VHDL (Very High Speed Integrated Circuit Hardware Description Language) as well as intermediate representations such as FIRRTL. Computer-readable code 702 may provide definitions embodying the concept using system-level modeling languages such as SystemC and SystemVerilog or other behavioral representations of the concepts that can be interpreted by a computer to enable simulation, functional and/or formal verification, and testing of the concepts.

Additionally or alternatively, the computer-readable code 702 may define a low level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code 702 a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code 702 may comprise a mix of code 702 representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code 702 defining instructions which are to be executed by the defined apparatus once fabricated.

Such computer-readable code 702 can be disposed in any known transitory computer-readable medium (such as wired or wireless transmission of code over a network) or non-transitory computer-readable medium 701 such as semiconductor, magnetic disk, or optical disc. An integrated circuit fabricated using the computer-readable code 702 may comprise components such as one or more of a central processing unit, graphics processing unit, neural processing unit, digital signal processor or other components that individually or collectively embody the concept.

Unless otherwise indicated, in the context of the present disclosure, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Furthermore, the terms “first,” “second” “third,” and the like are used to distinguish different aspects, such as different components, as one example, rather than supplying a numerical limit or suggesting a particular order, unless expressly indicated otherwise. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated.

In the preceding description, various aspects of claimed subject matter have been described. For purposes of explanation, specifics, such as amounts, systems and/or configurations, as examples, were set forth. In other instances, well-known features were omitted and/or simplified so as not to obscure claimed subject matter.

While certain features have been illustrated and/or described herein, many modifications, substitutions, changes and/or equivalents will now occur to those skilled in the art. It is, therefore, to be understood that the appended claims are intended to cover all modifications and/or changes as fall within claimed subject matter.

Some configurations of the present techniques are described by the following numbered clauses:

Clause 1: an Apparatus, Comprising:
a read signal output terminal;
a read signal input terminal to be in a precharge state prior to a read cycle and to be in a discharge state during the read cycle to indicate a first signal value;
a latch comprising a latch input/output terminal;
a transmission gate comprising a transmission gate input terminal coupled to the read signal input terminal and a transmission gate output terminal coupled to the latch input/output terminal; and
a combinatorial gate comprising a gate output terminal coupled to the read signal output terminal, a first gate input terminal coupled to the read signal input terminal, and a second gate input terminal coupled to the latch input/output terminal;
wherein the first gate input terminal is to drive the read signal output terminal during the read cycle responsive to the read signal input terminal in the discharge state.

Clause 2: The apparatus of clause 1, further comprising a bitline coupled to the read signal input terminal, wherein the bitline is to be in a high voltage state while the read signal input terminal is in the precharge state and to be in a low voltage state while the read signal input terminal is in the discharge state.

Clause 3: The apparatus of any preceding clause, wherein the combinatorial gate comprises a NAND gate.

Clause 4: The apparatus of any preceding clause, further comprising an inverter coupled between the read signal input terminal and the latch input/output terminal.

Clause 5: The apparatus of any preceding clause, wherein the combinatorial gate comprises a NOR gate.

Clause 6: The apparatus of any preceding clause, wherein, responsive to a sense signal received during the read cycle:
the transmission gate is to switchably couple the read signal input terminal to the latch input/output terminal, and
the latch is retain the precharge state or the discharge state from the read signal input terminal during the read cycle after receiving the sense signal.

Clause 7: The apparatus of any preceding clause, wherein the first gate input terminal is to drive the read signal output terminal during the read cycle prior to the latch retaining the discharge state.

Clause 8: The apparatus of any preceding clause, wherein the first gate input terminal is to drive the read signal output terminal during the read cycle prior to receiving the sense signal.

Clause 9: The apparatus of any preceding clause, where the latch is to drive the read signal output terminal during the read cycle after retaining the discharge state.

Clause 10: The apparatus of any preceding clause, wherein the latch comprises a tri-state latch to be in a high impedance state while receiving the sense signal and to be in a low impedance state after receiving the sense signal.

Clause 11: The apparatus of any preceding clause, wherein the read signal input terminal is to remain in the precharge state during the read cycle to indicate a second signal value

Clause 12: A method, comprising:
sensing a state of a read signal input terminal during a read cycle, the state comprising a precharge state or a discharge state;
retaining the state in a latch during the read cycle; and
driving a read signal output terminal via the read signal input terminal during the read cycle responsive to the discharge state.

Clause 13: The method of clause 12, further comprising:
driving the read signal output terminal via the latch during the read cycle responsive to the precharge state.

Clause 14: The method of any of clauses 12-13, further comprising:
retaining the state in the latch responsive to a sense signal received during the read cycle; and
driving the read signal output terminal via the latch responsive to the discharge state during the read cycle after receiving the sense signal.

Clause 15: The method of any of clauses 12-14, further comprising driving the read signal output terminal to the precharge state during the read cycle after receiving the sense signal.

Clause 16: The method of any of clauses 12-15, further comprising driving the read signal output terminal via a combinatorial gate connected to the read signal output terminal and the latch.

Clause 17: The method of any of clauses 12-16, wherein the combinatorial gate comprises a NAND gate.

Clause 18: The method of any of clauses 12-17, wherein the combinatorial gate comprises a NOR gate.

Clause 19: The method of any of clauses 12-19, wherein: the read signal input terminal is connected to a bitline; and the precharge state corresponds to a high voltage on the bitline.

Clause 20: A non-transitory computer-readable medium storing computer-readable code for fabrication of an apparatus comprising:
a read signal output terminal;
a read signal input terminal to be in a precharge state prior to a read cycle and to be in a discharge state during the read cycle to indicate a first signal value;
a latch comprising a latch input/output terminal;
a transmission gate comprising a transmission gate input terminal coupled to the read signal input terminal and a transmission gate output terminal coupled to the latch input/output terminal; and
a combinatorial gate comprising a gate output terminal coupled to the read signal output terminal, a first gate input terminal coupled to the read signal input terminal, and a second gate input terminal coupled to the latch input/output terminal;
wherein the first gate input terminal is to drive the read signal output terminal during the read cycle responsive to the read signal input terminal in the discharge state.

Clause 21: A non-transitory computer-readable medium storing computer-readable code for fabrication of an apparatus of any of clauses 1-11.

What is claimed is:

1. An apparatus, comprising:
a read signal output terminal;
a read signal input terminal to be in a precharge state prior to a read cycle and to be in a discharge state during the read cycle to indicate a first signal value;
a latch comprising a latch input/output terminal;
a transmission gate comprising a transmission gate input terminal coupled to the read signal input terminal and a transmission gate output terminal coupled to the latch input/output terminal; and
a combinatorial gate comprising a gate output terminal coupled to the read signal output terminal, a first gate input terminal coupled to the read signal input terminal, and a second gate input terminal coupled to the latch input/output terminal;
wherein the first gate input terminal is to drive the read signal output terminal during the read cycle responsive to the read signal input terminal in the discharge state.

2. The apparatus of claim 1, further comprising a bitline coupled to the read signal input terminal, wherein the bitline is to be in a high voltage state while the read signal input terminal is in the precharge state and to be in a low voltage state while the read signal input terminal is in the discharge state.

3. The apparatus of claim 1, wherein the combinatorial gate comprises a NAND gate.

4. The apparatus of claim 3, further comprising an inverter coupled between the read signal input terminal and the latch input/output terminal.

5. The apparatus of claim 1, wherein the combinatorial gate comprises a NOR gate.

6. The apparatus of claim 1, wherein, responsive to a sense signal received during
the read cycle:
the transmission gate is to switchably couple the read signal input terminal to the latch input/output terminal, and
the latch is retain the precharge state or the discharge state from the read signal input terminal during the read cycle after receiving the sense signal.

7. The apparatus of claim 6, wherein the first gate input terminal is to drive the read signal output terminal during the read cycle prior to the latch retaining the discharge state.

8. The apparatus of claim 7, wherein the first gate input terminal is to drive the read signal output terminal during the read cycle prior to receiving the sense signal.

9. The apparatus of claim 8, where the latch is to drive the read signal output terminal during the read cycle after retaining the discharge state.

10. The apparatus of claim 8, wherein the latch comprises a tri-state latch to be in a high impedance state while receiving the sense signal and to be in a low impedance state after receiving the sense signal.

11. The apparatus of claim 1, wherein the read signal input terminal is to remain in the precharge state during the read cycle to indicate a second signal value.

12. A method, comprising:
sensing a state of a read signal input terminal during a read cycle, the state comprising a precharge state or a discharge state;
retaining the state in a latch during the read cycle; and
driving a read signal output terminal via the read signal input terminal during the read cycle responsive to the discharge state.

13. The method of claim 12, further comprising:
driving the read signal output terminal via the latch during the read cycle responsive to the precharge state.

14. The method of claim 13, further comprising:
retaining the state in the latch responsive to a sense signal received during the read cycle; and
driving the read signal output terminal via the latch responsive to the discharge state during the read cycle after receiving the sense signal.

15. The method of claim 14, further comprising driving the read signal output terminal to the precharge state during the read cycle after receiving the sense signal.

16. The method of claim 12, further comprising driving the read signal output terminal via a combinatorial gate connected to the read signal output terminal and the latch.

17. The method of claim 16, wherein the combinatorial gate comprises a NAND gate.

18. The method of claim 16, wherein the combinatorial gate comprises a NOR gate.

19. The method of claim 12, wherein:
the read signal input terminal is connected to a bitline; and
the precharge state corresponds to a high voltage on the bitline.

20. A non-transitory computer-readable medium storing computer-readable code for
fabrication of an apparatus comprising:
a read signal output terminal;
a read signal input terminal to be in a precharge state prior to a read cycle and to be in a discharge state during the read cycle to indicate a first signal value;
a latch comprising a latch input/output terminal;
a transmission gate comprising a transmission gate input terminal coupled to the read signal input terminal and a transmission gate output terminal coupled to the latch input/output terminal; and
a combinatorial gate comprising a gate output terminal coupled to the read signal output terminal, a first gate input terminal coupled to the read signal input terminal, and a second gate input terminal coupled to the latch input/output terminal;
wherein the first gate input terminal is to drive the read signal output terminal during the read cycle responsive to the read signal input terminal in the discharge state.
